(19) United States
(12) Patent Application Publication
(10) Pub. No.: US 2024/0188213 A1
(43) Pub. Date: Jun. 6, 2024

(54) CIRCUIT BOARD FOR A CONTROL DEVICE OF A VEHICLE, AND METHOD FOR MANUFACTURING OF SUCH A CIRCUIT BOARD

(71) Applicant: LISA DRÄXLMAIER GMBH, Vilsbiburg (DE)

(72) Inventor: Andreas BRINKMANN, Dachau (DE)

(73) Assignee: LISA DRÄXLMAIER GMBH, Vilsbiburg (DE)

(21) Appl. No.: 18/405,252

(22) Filed: Jan. 5, 2024

Related U.S. Application Data
(63) Continuation of application No. PCT/EP2022/068138, filed on Jun. 30, 2022.

(30) Foreign Application Priority Data
Jul. 5, 2021 (DE) 102021117278.0

(51) Int. Cl. H05K 1/03

(52) U.S. Cl. CPC H05K 1/038; H05K 1/0306; H05K 1/036; H05K 2201/029

(57) ABSTRACT

A circuit board, in particular for a control device of a vehicle, includes a core made of at least two layers of resin impregnated glass textile and two conductor planes of the circuit board. The glass textile layers are disposed between the conductor planes and the conductor planes are on opposite sides of the core. The glass textile layers are each between 50 micrometers and 150 micrometers thick and have a resin content of between 58 percent by volume and 74 percent by volume. The conductor planes are each between 20 micrometers and 50 micrometers thick.

### CROSS-REFERENCE TO RELATED APPLICATIONS

This application is a continuation of International Application No. PCT/EP2022/068138, filed on Jun. 30, 2022, which claims priority to and the benefit of German Application No. 102021117278.0, filed on Jul. 5, 2021. The disclosures of the above applications are incorporated herein by reference.

### FIELD

The present disclosure relates to a circuit board for a control device of a vehicle, and a method for manufacturing a circuit board for a control device of a vehicle.

### BACKGROUND

The statements in this section merely provide background information related to the present disclosure and may not constitute prior art.

An electrical circuit can be built on a circuit board. In particular, flame retardant circuit boards can be used in vehicles. Flame retardant circuit boards can be multi-layer laminates made of glass-fiber reinforced plastic and conductor paths. The circuit boards can be built in layers on a central core. The core can be a cost-effective standard component used millions of times.

The core can have sufficient properties in normal situations. However, when used in the vehicle, situations or environmental conditions can prevail that can lead to migration effects in the core.

### SUMMARY

This section provides a general summary of the disclosure and is not a comprehensive disclosure of its full scope or all of its features.

The present disclosure provides an improved circuit board for a control device of a vehicle, and an improved method for manufacturing such a circuit board. Here, an improvement can concern, for example, an improved service life, in particular a greater insensitivity with respect to migration effects.

Under the influence of moisture and/or due to electro-corrosion, copper ions can be released from metallic components of an electrical circuit. In particular with high DC voltages, the copper ions can migrate along glass fibers of a circuit board. This migration can be described as electro-migration and lead to fault currents in the electrical circuit and can be referred to as conductive anodic filament (CAF). CAF can be increasingly observed in the field of electro-mobility due to the high electrical voltages of 400V or more frequently occurring there, for example.

Circuit boards are built in layers on a core. Here, layers with electrically conducting conductor paths alternate with electrically insulating layers. With conventional circuit boards, a prefabricated core made of a plurality of layers of resin impregnated glass fabric is used. The layers are typically 200 micrometers thick and have a resin content of less than 45 percent. The core can have a thickness in the range of, for example, 600 micrometers. The core can have a coarse fiberglass structure. The layered structure can be performed on both sides of the core.

With the approach presented here, an alternative structure of a circuit board is presented. In particular, an alternative structure of the core of the circuit board is presented. Here, finer fiberglass fabrics are used in combination with a higher resin content. A potential of a migration of copper ions along glass fibers of the fiberglass fabric can thereby be reduced. In particular, already available materials are used in this case in order to keep additional costs as low as possible, while the materials are skillfully processed and/or combined in order to be able to create the desired physical properties of the circuit board.

A circuit board is presented, in particular, for a control device of a vehicle. The circuit includes a core made of at least two layers of resin impregnated glass textile and two conductor planes of the circuit board, where the glass textile layers are disposed between the conductor planes and the conductor planes are on opposite sides of the core. The glass textile layers are each between 50 micrometers and 150 micrometers thick and have a resin content between 58 percent by volume and 74 percent by volume. The conductor planes are each between 20 micrometers and 50 micrometers thick.

Furthermore, a method is presented for manufacturing a circuit board, in particular, for a control device of a vehicle, in which a core of the circuit board is laminated from two half cores. The half-cores each have at least one layer of resin impregnated glass textile and one conductor plane of the circuit board, where the glass textile layers are disposed between the conductor planes and the conductor planes are on opposite sides of the core. The glass textile layers are each between 50 micrometers and 150 micrometers thick and have a resin content between 58 percent by volume and 74 percent by volume, and the conductor planes are each between 20 micrometers and 50 micrometers thick.

A circuit board can be a multi-layer structure of conductor planes with electrically conducting conductor paths and insulating intermediate layers disposed therebetween. The circuit boards can have, for example, up to 50 layers. The conductor paths can be made of, for example, a copper material. The circuit board can have flame retardant properties. The intermediate layers can consist of a resin impregnated glass textile. The resin can be, for example, an epoxy resin.

The glass textile can be a fabric, interlaced yarn, knitted fabric, mesh, or core with oriented glass fibers or filaments. The glass textile can also be a non-oriented mat, non-woven fabric, or felt with non-oriented glass fibers or filaments.

A core of the circuit board can be an electrically insulating intermediate layer disposed centrally in the circuit board. The core can also consist of a resin impregnated glass textile. The conductor planes and the intermediate layers can be built in layers on both sides on the core. The core can form a neutral fiber of the circuit board. The core can be a carrier for building the intermediate layers and conductor planes. The core can include receptacles for aligning or centering in a corresponding tool. The intermediate layers can include corresponding receptacles. In the tool, the receptacles can be, for example, attached to pins and aligned in this way.

The layered structure can be referred to as laminating. Glass textile can be impregnated with a resin, and firmly connected with other layers by an adhesive effect of the resin. A resin content of the laminate can be set by precisely dosing the resin. A layer thickness of a layer is determined, inter alia, by a fineness of the glass textile. With the approach presented here, at least for the core, a finer glass textile with a higher resin content is used than for cores of conventional circuit boards. An improved wetting of the glass textile is achieved by the increased resin content. Due to the improved wetting, an increased adhesive effect of the resin on the glass fibers of the glass textile results. Thus, the glass fibers cannot be torn out from the resin so quickly during the drilling process. For the glass textile, flattened yarns made of many glass fibers or filaments (spread fibers) are advantageous, since good penetration of the glass fiber with the resin can be achieved with flattened yarns.

For manufacturing the core, two half cores can be laminated together. A half core can be an intermediate product that is easily available. A half core consists of at least one layer of resin impregnated glass textile with a conductor plane thereon. The half cores can be processed already cured. Further, half cores can also be used for the construction of further intermediate layers and conductor planes of the circuit board. Then, at least one layer of resin impregnated glass textile can be laminated onto an available inner conductor plane, and a further half core can be laminated onto the glass textile.

The core can include at least another layer of resin impregnated glass textile. The other glass textile layer can be disposed between the half cores and laminated with the half cores. The other layer can be disposed in a central plane of the circuit board. Mechanical properties of the circuit board can be set by additional layers.

The glass fibers of the glass textile can have a diameter between 33 micrometers and 180 micrometers, and more particularly in another form between 33 micrometers and 95 micrometers. The glass fibers can be used as single filaments. The filaments can be, for example, woven, weaved, knitted, braided, or matted. Such glass textiles can be referred to as monofilament. Alternatively, a plurality of glass fibers can be collected into a bundle, and the bundle can be woven, weaved, knitted, braided, or matted.

The glass textile can be embodied as glass fabric in plain weave. A plain weave can produce a particularly fine glass textile. The core can thus have a high flexibility.

The circuit board can include at least four conductor planes and at least two intermediate layers. An intermediate layer made of at least two further layers of resin impregnated glass textile can be disposed between each two adjacent conductor planes. The glass textile layers can also each be between 50 micrometers and 150 micrometers thick and have a resin content between 58 percent by volume and 74 percent by volume.

As the intermediate layers, at least two layers of resin impregnated glass textile can be laminated onto the respective outermost conductor planes. The glass textile layers of the intermediate layers can be stacked onto the conductor planes and laminated to the conductor planes and among one another. The layers can be aligned with respect to one another and with respect to the already present conductor planes. The layers for the laminating can then be compressed under temperature and pressure.

The glass textile layers can be provided as prepregs. A prepreg can be a glass textile pre-impregnated with a synthetic resin. The prepreg can be ready to process. The prepreg can have a pre-specified resin content. The synthetic resin can be a two-component resin made of resin and hardener. The hardener of the resin can already be added to the resin. The prepreg can be processed cooled. The prepreg can cure without further additives under the influence of pressure and temperature. The prepreg can also be impregnated with a one-component resin. A curing process of the synthetic resin can then be accelerated by the influence of temperature and/or ultraviolet light. The prepreg can be processed easily. For example, the prepreg can be dry to the touch during processing. The half cores can also be prepregs.

The conductor planes can be structured after laminating the half cores. During structuring, the conductor paths can be formed with, for example, 200 μm width, and 200 μm spacing between one another. In this case, a conductor plane can have, for example, a height of 24.9 μm. For example, the conductor paths can be masked, and unmasked metal material can be etched away.

The conductor planes can be structured before laminating the next intermediate layers. The circuit board can be manufactured step-by-step with a defined sequence of steps.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a cross-sectional view of a circuit board according to one form of the present disclosure.

The FIGURE is only a schematic representation and serves only to explain the present disclosure. Identical or identically functioning elements are consistently provided with the same reference numerals.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

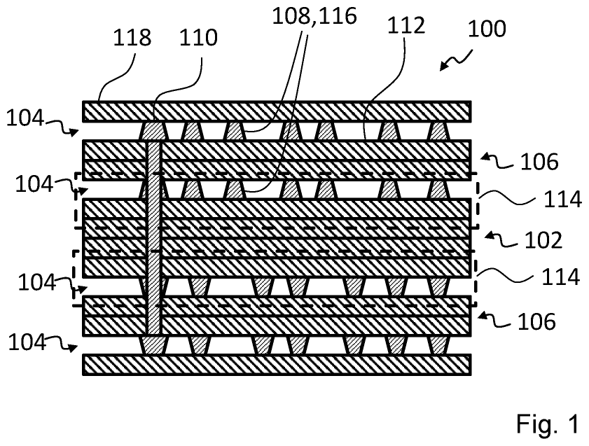

FIG. 1 shows a cross-sectional view of a circuit board 100 according to one form of the present disclosure. The circuit board 100 includes a core 102, four conductor planes 104, and at least two intermediate layers 106. The circuit board 100 is a simplified representation and can also include a larger number of conductor planes 104. For example, the circuit board 100 can include up to 50 conductor planes 104, and 48 intermediate layers 106.

In a conductor plane 104, conductor paths 108 are disposed side by side. Different conductor paths 108 in the same conductor plane 104 are disposed laterally spaced and electrically insulated from one another. Conductor paths 108 disposed in different conductor planes 104 can cross over one another. The intermediate layer 106 disposed therebetween insulates the crossing conductor paths 108 from one another.

The individual conductor planes 104 can be electrically connected to one another by through-connections 110. Via through-connections 110, a current flow can be made possible through the electrically insulating intermediate layers 106, or through the electrically insulating core 102. Here, a through-connection 110 penetrates both intermediate layers 106 and the core 102. The through-connection 110 thus connects conductor paths 108 in all conductor planes 104 to one another. Through-connections 110 can be disposed, for example, in holes drilled in the circuit board 100. Through-connections 110 can also be buried within the circuit board 100 by being covered by further outside intermediate layers 106.

The circuit board 100 is a flame retardant circuit board 100 for a control device of a vehicle. The core 102 includes at least two layers 112 of resin impregnated glass textile. Two conductor planes 104 abut against opposite surfaces on the core 102. An intermediate layer 106 made of at least two further layers 112 of resin impregnated glass textile is disposed on each of the conductor planes 104. An intermediate layer 106 or the core 102 is disposed as insulation between each two conductor planes 104. The outermost conductor planes 104 are disposed outside on the outermost intermediate layers 106.

The glass textile layers 112 are each between 50 micrometers and 150 micrometers thick. The layers 112 have a resin content between 58 percent and 74 percent. The conductor planes 104 are each between 20 micrometers and 50 micrometers thick.

With the approach presented here, for manufacturing the circuit board 100, first of all, two half cores 114 are connected to each other in order to form the core 102. A half core 114 consists of a copper layer 116 on at least one layer 112 of resin impregnated glass textile. For manufacturing the core 102, the half cores 114 are placed on top of each other with the glass textile layers 112 disposed between the conductor planes 104 and laminated under temperature and pressure. The copper layer 116 can be structured after laminating to form the conductor paths 108. The half cores 114 can be already cured pre-products. The half cores 114 can be wetted with synthetic resin and connected to each other. Likewise, the synthetic resin can be disposed as a film between the half cores 114.

In one form, for structuring the conductor paths 108, an exposable mask 118 is disposed on the respective outermost conductor plane 104. The mask 118 can be selectively exposed. Exposed regions of the mask 118 cure and are then resistant to an etching agent. Unexposed regions of the mask 118 are rinsed. The copper layer 116 exposed there is removed by the etching agent to provide intermediate spaces between the conductor paths 108. The exposed regions can subsequently also be removed. The next intermediate layer 106 made of at least two further layers 112 of resin impregnated glass textile, with a thickness between 50 micrometers, and 150 micrometers and a resin content between 58 percent and 74 percent, is then laminated onto the structured outermost conductor plane 104. The next conductor plane 104 is then in turn applied as a copper layer 116 onto this intermediate layer 106.

In one form, at least one additional layer 112 of resin impregnated glass textile is disposed between the half cores 114 and laminated with the half cores 114 to the core 102. The additional layer 112 is also between 50 micrometers and 150 micrometers thick and has a resin content between 58 percent and 74 percent. The additional layer 112 of resin impregnated glass textile can provide the reactive synthetic resin desired for laminating between the half cores 114. A separate application of resin can then be omitted.

Since the devices and methods described above in detail are exemplary forms, they can be modified in a conventional manner to a wide extent by the person skilled in the art without leaving the field of the present disclosure. In particular, the mechanical assemblies and the size ratios of the individual elements with respect to one another are only exemplary.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A circuit board for a control device of a vehicle, the circuit board including:
a core made of at least two layers of resin impregnated glass textile; and
two conductor planes, wherein the at least two layers of resin impregnated glass textile are disposed between the conductor planes, and the conductor planes are on opposite sides of the core, wherein the at least two layers of resin impregnated glass textile are each between 50 micrometers and 150 micrometers thick and have a resin content between 58 percent by volume and 74 percent by volume, and wherein the conductor planes are each between 20 micrometers and 50 micrometers thick.

2. The circuit board according to claim 1, wherein the core includes at least one further layer of resin impregnated glass textile.

3. The circuit board according to claim 1, wherein the at least two layers of resin impregnated glass textile includes a plurality of glass fibers, and wherein the glass fibers of the at least two layers of resin impregnated glass textile have a diameter of between 33 micrometers and 95 micrometers.

4. The circuit board according to claim 1, wherein the at least two layers of resin impregnated glass textile is embodied as a glass fabric in plain weave.

5. The circuit board according to claim 1, further comprising at least four conductor planes and at least two intermediate layers, wherein an intermediate layer of the at least two intermediate layers includes at least two further layers of resin impregnated glass textile, wherein an intermediate layer of the at least two intermediate layers is disposed between each two adjacent conductor planes of the at least four conductor planes, and wherein the at least two further layers of resin impregnated glass textile are each between 50 micrometers and 150 micrometers thick and have a resin content between 58 percent by volume and 74 percent by volume.

6. A method for manufacturing a circuit board for a control device of a vehicle, the method comprising laminating a core of the circuit board from two half cores,
wherein the two half cores each include at least one layer of resin impregnated glass textile and one conductor plane of the circuit board,
wherein the resin impregnated glass textile layers are disposed between the conductor planes and the conductor planes are on opposite sides of the core,
wherein the resin impregnated glass textile layers are each between 50 micrometers and 150 micrometers thick and have a resin content of between 58 percent by volume and 74 percent by volume, and
wherein the conductor planes are each between 20 micrometers and 50 micrometers thick.

7. The method according to claim 6, further comprising laminating at least two layers of resin impregnated glass textile as intermediate layers of the circuit board onto the conductor planes of the core, wherein the at least two layers of resin impregnated glass textile are each between 50 micrometers and 150 micrometers thick and have a resin content of between 58 percent by volume and 74 percent by volume.

8. The method according to claim 7, wherein the resin impregnated glass textile layers of the intermediate layers are stacked onto the conductor planes and laminated with the conductor planes and among one another.

9. The method according to claim 7, wherein the conductor planes are structured before laminating the intermediate layers.

10. The method according to claim 6, wherein the resin impregnated glass textile layers are provided as prepregs.

11. The method according to claim 6, wherein the conductor planes are structured after laminating the two half cores.
